(19) United States
(12) Patent Application Publication
(10) Pub. No.: US 2018/0013020 A1
(43) Pub. Date: Jan. 11, 2018

(54) METAL CHALCOGENIDE DEVICE AND PRODUCTION METHOD THEREFOR

(71) Applicants: LG ELECTRONICS INC., Seoul (KR); RESEARCH & BUSINESS FOUNDATION SUNGKYUNKWAN UNIVERSITY, Suwon-si, Gyeonggi-do (KR)

(72) Inventors: Minseok CHOI, Seoul (KR); Changgu LEE, Suwon-si (KR); Hunyoung BARK, Suwon-si (KR); Jinhwan LEE, Suwon-si (KR)

(73) Assignees: LG ELECTRONICS INC., Seoul (KR); RESEARCH & BUSINESS FOUNDATION SUNGKYUNKWAN UNIVERSITY, Suwon-si, Gyeonggi-do (KR)

(21) Appl. No.: 15/544,170

(22) PCT Filed: Sep. 30, 2015
(86) PCT No.: PCT/KR2015/010293

§ 371 Date: Jul. 17, 2017

(30) Foreign Application Priority Data
Jan. 29, 2015 (KR) 10-2015-0014291

(51) Int. Cl. H01L 31/0224; H01L 31/0392; H01L 31/0236; C01B 17/42; C01G 33/00; C01G 39/06

(52) U.S. Cl. CPC H01L 31/022466; H01L 31/0392; H01L 31/0236; C01G 33/00; C01G 39/06; C01B 17/42; H01L 31/022425

(57) ABSTRACT

The present invention relates to a chalcogenide device and particularly to a metal chalcogenide device using transition metal chalcogenides as electrodes and a production method therefor. The metal chalcogenide device according to the present invention may comprise: a substrate; an oxide layer positioned on the substrate; a first conductive metal chalcogenide layer positioned on the oxide layer; and first and second electrodes, which are positioned apart from one another on the metal chalcogenide layer and comprise metal chalcogenides.

### TECHNICAL FIELD

The present invention relates to a chalcogenide device, and particularly to a metal chalcogenide device using transition metal chalcogenide as an electrode, and a method of manufacturing the same.

### BACKGROUND ART

Two-dimensional materials are attracting a great deal of attention as next-generation semiconductor materials which will replace silicon-based semiconductors. As the integration degree of circuits increases and the length of gate channels decreases to 10 nanometers or less in the silicon-based semiconductor industry, drawbacks such as short-channel effect occur.

A two-dimensional material can overcome a short channel effect due to very small thickness corresponding to one or two atom layers, and is transparent and flexible, thus being actively researched as a material for next-generation electronic and photoelectric material devices.

Among elements which belong to the group 16 of the periodic table, five elements of oxygen (O), sulfur (S), selenium (Se), tellurium (Te) and polonium (Po) are referred to as oxygen group elements and, thereamong, only three elements of sulfur, selenium and tellurium are referred to as sulfur group elements or chalcogens.

A metal chalcogenide is a compound of a transition metal and chalcogen, which is a nano material having a similar structure to graphene. The metal chalcogenide has a very small thickness corresponding to the thickness of several atomic layers, is thus soft and transparent and exhibits various electrical properties such as semiconductor and conductor properties.

At least part of metal chalcogenides exhibit properties of two-dimensional materials, and in particular, metal chalcogenides having semiconductor properties have a suitable band gap and electron mobility of hundreds of cm²/V.s, thus being applicable to semiconductor devices such as transistors and having great potential as elastic transistor devices.

Therefore, there is a need for a device using properties of metal chalcogenides and a method of manufacturing the same.

### DISCLOSURE

### Technical Problem

One object of the present invention devised to solve the problem lies in a metal chalcogenide device with a contact resistance of an electrode, and a method of manufacturing the same.

In addition, another object of the present invention devised to solve the problem lies in a metal chalcogenide device including a metal chalcogenide layer having p-type conductivity and a method of manufacturing the same.

### Technical Solution

The object of the present invention can be achieved by providing a metal chalcogenide device including a substrate, a metal chalcogenide layer with a first conductivity disposed on the substrate, and a first electrode and a second electrode spaced from each other on an upper surface or a side surface of the metal chalcogenide layer, the first electrode and the second electrode including metal chalcogenide.

Here, the first conductivity may be p-type.

Here, at least one of the first electrode and the second electrode may include Nb.

Here, the metal chalcogenide layer may include MoS₂.

Here, at least one of the first electrode and the second electrode may include NbS₂.

Here, the metal chalcogenide layer may contact at least one of the first electrode and the second electrode in a side surface direction.

Here, a diffusion area having a relatively high first conductivity may be disposed between the metal chalcogenide layer and at least one of the first electrode and the second electrode.

Here, the metal chalcogenide device may further include a gate insulator disposed on the metal chalcogenide layer, and a gate electrode disposed on the gate insulator.

In another aspect of the present invention, provided herein is a metal chalcogenide device including a substrate, a channel layer including a p-type MoS₂ thin film disposed on the substrate, a first electrode connected to the channel layer at a first position in a side surface direction, the first electrode including Nb, a second electrode connected to the channel layer in a side surface direction at a second position spaced from the first position, the second electrode including Nb, and a diffusion area disposed at least one position of between the first electrode and the channel layer, and between the second electrode and the channel layer, the diffusion area being a region where a Nb atom diffuses into the channel layer.

Here, the diffusion area may have a higher conductivity than that of the channel layer.

Here, the Nb atom may be used as a dopant in the channel layer.

Here, the metal chalcogenide device may further include a gate insulator disposed on the channel layer, and a gate electrode disposed on the gate insulator.

In another aspect of the present invention, provided herein is a method of manufacturing a metal chalcogenide device including forming a first metal chalcogenide layer on a semiconductor substrate with a first conductivity where an oxide layer is disposed, forming metal patterns spaced from each other at a position where the metal patterns contact the first metal chalcogenide layer, and supplying a chalcogen-containing gas to the metal pattern to form the metal pattern into an electrode including a second metal chalcogenide.

Here, the first metal chalcogenide layer may include MoS₂.

Here, the metal pattern may include Nb.

Here, the forming the metal pattern into the electrode may include allowing the first metal chalcogenide layer to have the first conductivity by an atom contained in the metal pattern.

Here, the first metal chalcogenide layer may contact the metal pattern in a side surface direction.

Here, the forming the metal pattern may include forming a mask pattern having an open part where the metal pattern is to be formed, on the first metal chalcogenide layer, removing the opened first metal chalcogenide layer using the mask pattern, forming the metal pattern in the area from which the first metal chalcogenide layer is removed, and removing the mask pattern.

Here, the first conductivity may be p-type.

Here, the method may further include forming a gate insulator between the metal patterns, and forming a gate electrode on the gate insulator.

### Advantageous Effects

The present invention has effects of providing a metal chalcogenide layer having a p-type conductivity and greatly reducing contact resistance of an electrode of the metal chalcogenide device.

### DESCRIPTION OF DRAWINGS

FIG. 1 is a schematic sectional view illustrating a metal chalcogenide device according to an embodiment of the present invention.

FIG. 2 is a schematic sectional view illustrating a metal chalcogenide device according to another embodiment of the present invention.

FIGS. 3 to 5 are sectional views illustrating a process of manufacturing a metal chalcogenide device according to an embodiment of the present invention.

FIGS. 6 to 10 are sectional views illustrating a process of manufacturing a metal chalcogenide device according to another embodiment of the present invention.

FIGS. 11 to 14 are sectional views illustrating a process of manufacturing a metal chalcogenide device according to another embodiment of the present invention.

FIG. 15 is a graph showing a transfer curve of a metal chalcogenide device.

### BEST MODE

Reference will now be made in detail to the preferred embodiments of the present invention, examples of which are illustrated in the accompanying drawings.

However, the present invention allows various modifications and variations and specific embodiments thereof are exemplified with reference to the drawings and will be described in detail. The present invention should not be construed as limited to the embodiments set forth herein and includes modifications, equivalents and substitutions compliant with the spirit or scope of the present invention defined by the appended claims.

It will be understood that when an element such as a layer, area or substrate is referred to as being “on” another element, it may be directly on the element, or one or more intervening elements may also be present therebetween.

In addition, it will be understood that although terms such as “first” and “second” may be used herein to describe elements, components, areas, layers and/or regions, the elements, components. areas, layers and/or regions should not be limited by these terms.

In addition, it is not deemed that processes described in the present invention should be conducted in order. For example, when several steps are mentioned, the steps may not be performed in order.

A two-dimensional material grabs much attention as a next-generation material in the semiconductor industry. Among two-dimensional materials, MoS₂, which is a transition metal chalcogen compound, exhibits direct transition type semiconductor properties in a single layer and has a bandgap of 1.8 eV. MoS₂ is a potential material since it has a bandgap without any separate treatment process and exhibits n-type semiconductor characteristics.

However, MoS₂ has a drawback of lower mobility than graphene which is another two-dimensional material. In addition, there is no established doping technology to implement p-type semiconductors essential to construct various device structures and circuits.

In order to apply MoS₂ as a next-generation electronic and photoelectric device to a variety of invention fields such as flat panel displays and solar cells, technology to improve charge mobility and implement p-type semiconductors is required.

The present invention provides a p-type MoS₂ device which is manufactured by using a top-surface or side-surface contact method to reduce a contact resistant and utilizing NbS₂ as another transition metal chalcogen compound as an electrode and a method of manufacturing the same.

NbS₂, like MoS₂, which is a (transition) metal chalcogen compound, has a similar crystal structure to MoS₂ However, NbS₂ has properties of a conductor, unlike MoS₂. The present invention suggests formation of composite structures using transition metal chalcogen compounds having various properties and will be expected to greatly affect studies on composite structures between various transition metal chalcogen compounds in the future.

Since NbS₂ and MoS₂ have similar crystal structures, when NbS₂ is used as an electrode, contact resistance can be reduced, as compared to when a general metal is used. When the side-surface contact method suggested in the present invention is further used, contact resistance can be further reduced.

High contact resistance is a determining factor limiting performance of an device. The way to reduce contact resistance suggested in the present invention will be expected to play an important role in improving device performance of MoS₂ in the future.

Meanwhile, doping is a technology which should be established in order to apply MoS₂ to the real industry. MoS₂ has n-type semiconductor properties in itself and is doped with a p-type semiconductor when a small amount of Nb atom is added to it.

The present invention suggests a manufacturing method which includes depositing a Nb metal in a part where an electrode is connected to MoS₂ and diffusing a small amount of Nb into MoS₂ while synthesizing NbS₂ at high temperature. Technology to manufacture both polarities of the MoS₂ semiconductor is suggested by a method of doping MoS₂, an n-type semiconductor, with a p-type semiconductor.

The present invention described above will be expected to be actively used in research related to a variety of devices and circuits using MoS₂. Specifically, the present invention will be expected to be essentially used to develop and study PN junction structures using n-type and p-type semiconductors and CMOS transistors, and furthermore, to manufacture optical sensors using two-dimensional materials, light emitting devices, photodetectors, photomagnetic memory devices, photocatalysts, flat panel displays, solar cells and the like as well as electronic and photoelectric devices based on next-generation transparent and flexible semiconductors.

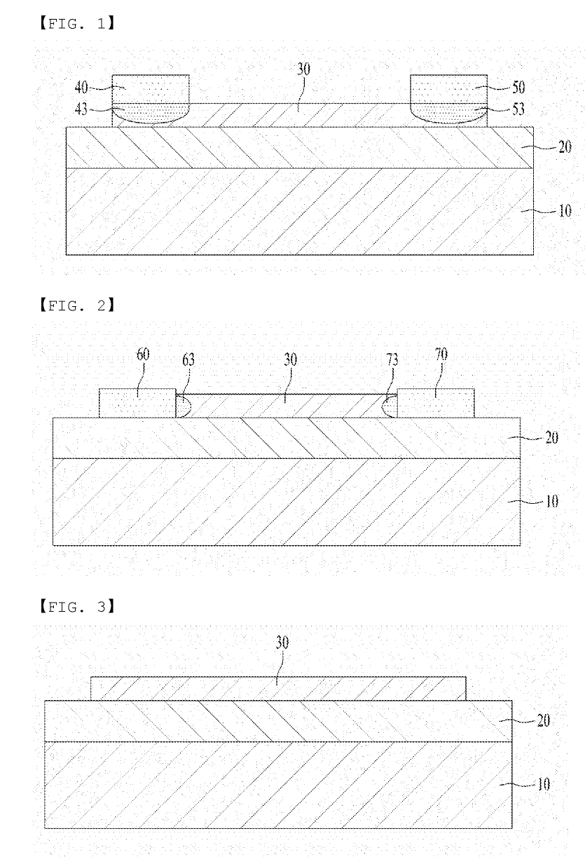

FIG. 1 is a schematic sectional view illustrating a metal chalcogenide device according to an embodiment of the present invention.

Referring to FIG. 1, the metal chalcogenide device includes a metal chalcogenide layer 30 with a first conductivity disposed on a substrate 10.

In addition, a first electrode 40 and a second electrode 50, which each include metal chalcogenide, are disposed on the metal chalcogenide layer 30 such that they are spaced from each other.

The substrate 10 may be a semiconductor substrate, for example, a silicon (Si) semiconductor substrate. In this case, an oxide layer 20 may be disposed between the substrate 10 and the metal chalcogenide layer 30 and the oxide layer 20 may be a silicon oxide (SiO₂) layer.

The substrate 10 may include an insulating material such as sapphire or glass. In this case, a separate oxide layer may not be disposed.

The first conductivity may be a p-type conductivity. Accordingly, a metal chalcogenide layer having p-type conductivity can be acquired. In this case, the substrate 10 may also be a semiconductor substrate with p-type conductivity.

Here, the metal chalcogenide layer 30 may include a thin film, for example, a MoS₂ thin film, including a single atomic layer or a plurality of atomic layers made of one kind of transition metal chalcogenide material.

Such a metal chalcogenide layer 30 may be used as a channel layer of a field effect transistor (FET) device made of a metal-oxide-semiconductor. In this case, the first electrode 40 may be used as a source electrode and the second electrode 50 may be used as a drain electrode. In addition, a separate metal electrode may be further provided on each of the first electrode 40 and the second electrode 50, and the metal electrode may be used as each of the source electrode and the drain electrode.

The semiconductor substrate 10 may be provided with a separate gate electrode. This device structure may constitute a back-gate type FET device.

Meanwhile, a gate insulator and a gate electrode (91, 90; see FIG. 14 may be further disposed on the metal chalcogenide layer 30. This device structure may constitute a top-gate type FET device.

The metal chalcogenide layer 30 may have chemical formula MX₂, wherein M is any one of Mo, W, Tc, Re, Pd and Pt, and X is any one of S, Se and Te.

That is, the metal chalcogenide layer 30 may include at least one of MoSe₂, WS₂, WSe₂, TiS₂, TiSe₂, TiTe₂, HfS₂, HfSe₂, HfTe₂, ZrS₂, ZrSe₂, ZrTe₂, TcS₂, TcSe₂, TcTe₂, ReS₂, ReSe₂, ReTe₂, PdS₂, PdSe₂, PtS₂, and PtSe₂. Hereinafter, an example in which the metal chalcogenide layer 30 is a MoS₂ layer will be described.

In this case, at least one of the first electrode 40 and the second electrode 50 may include a Group 5 metal chalcogenide material, that is, a Group 5 metal including at least one of V, Nb and Ta. In addition, at least one of the first electrode 40 and the second electrode 50 may include S, Se and Te bonded to the Group 5 metal.

For example, at least one of the first electrode 40 and the second electrode 50 may be NbS₂. Hereinafter, an example in which the first electrode 40 and the second electrode 50 are formed using NbS₂ will be described.

NbS₂ is a two-dimensional material having a similar crystal structure to MoS₂ NbS₂ is classified as a transition metal chalcogen, like MoS₂ but has a conductor property. In addition, when a Nb atom is partially added to MoS₂, the Nb atom serves as a dopant so that MoS₂ can exhibit p-type conductivity.

Since NbS₂ has a similar crystal structure to MoS₂, the contact resistance between the metal chalcogenide layer 30, and the first electrode 40 and the second electrode 50 is reduced, so that some Nb atoms of the first electrode 40 and the second electrode 50 diffuse into MoS₂, and the p-type semiconductor can thus be manufactured. In this case, NbS₂ constituting the first electrode 40 and the second electrode 50 may contact the top surface of the metal chalcogenide layer 30 (top-surface contact method) or the side surface of the metal chalcogenide layer 30 (side-surface contact method).

As such, since some of the Nb atoms contained in the electrodes 40 and 50 diffuse into MoS₂ to constitute a p-type semiconductor, diffusion areas 43 and 53 having a higher conductivity can be disposed between the metal chalcogenide layer 30 and at least one of the first electrode 40 and the second electrode 50.

Through these diffusion areas 43 and 53, an energy band structure can be smoothly connected between the metal chalcogenide layer 30, and the first electrode 40 and the second electrode 50. That is, a band structure having a broad gradient can be formed.

Accordingly, an energy barrier therebetween is reduced so that flow of charges can be facilitated.

FIG. 1 illustrates a top-surface contact type metal chalcogenide device. Referring to FIG. 1, as mentioned above, the effect of p-type doping can be obtained by using NbS₂ for electrodes 40 and 50 so that a p-type MoS₂ device can be realized.

By providing an electrode using NbS₂ having a similar crystal structure to this MoS₂ layer, the metal chalcogenide device can have an effect of exhibiting reduced contact resistance as compared to a structure in which the metal chalcogenide device directly contacts the metal electrode. In addition, such a top-surface contact type offers an easy manufacture process, as compared to the side-surface contact type method.

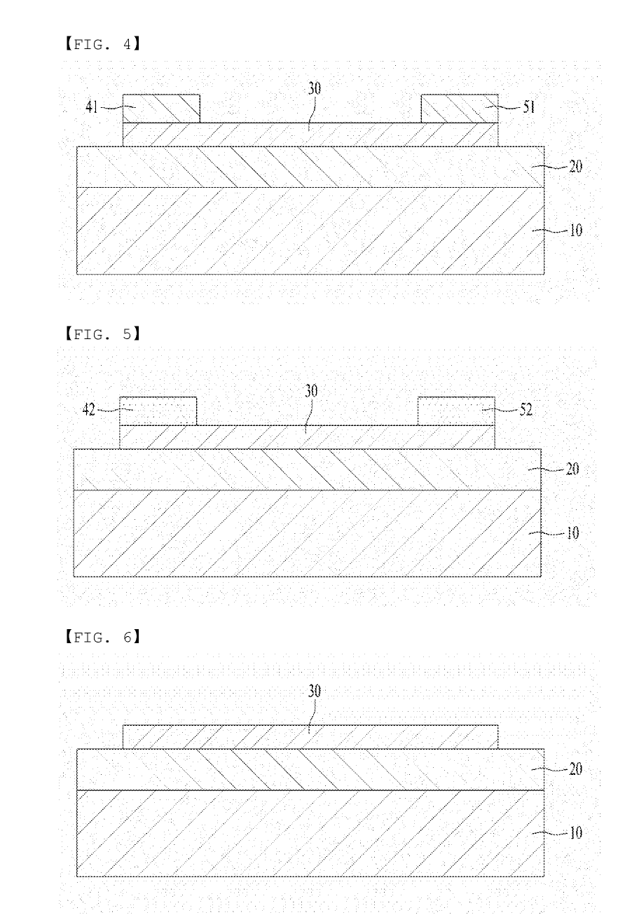

FIG. 2 is a schematic sectional view illustrating a metal chalcogenide device according to another embodiment of the present invention.

FIG. 2 illustrates an example of a side-surface contact type metal chalcogenide device in which NbS₂ constituting the first electrode 60 and the second electrode 70 contacts the side surface of the metal chalcogenide layer 30.

In such a structure, NbS₂, a two-dimensional material, may contact the metal chalcogenide layer 30 made of MoS₂, another two-dimensional material, in a side surface direction.

Since the two-dimensional material has a structure in which respective atoms are bonded and disposed on one plane, its bonding strength in a vertical direction is as low as an intermolecular bonding strength. However, interatomic bonds may be formed in a side surface direction and contact resistance between the electrodes 60 and 70, and the metal chalcogenide layer 30 can thus be significantly reduced.

Accordingly, contact in a parallel direction enabling easy charge transfer of the two-dimensional material leads to great improvement in the device performance of MoS₂.

As mentioned above, since some of the Nb atoms contained in the electrodes 60 and 70 diffuse into MoS₂ to form a p-type semiconductor, diffusion areas 63 and 73 having higher conductivity may be disposed between the metal chalcogenide layer 30 and at least one of the first electrode 40 and the second electrode 50.

Through these diffusion areas 63 and 73, an energy band structure can be smoothly connected between the metal chalcogenide layer 30, and the first electrode 60 and the second electrode 70. That is, a band structure having a broad gradient can be formed.

Accordingly, an energy barrier therebetween is reduced so that flow of charges can be facilitated owing to strong interatomic bonding.

The contents described with reference to FIG. 1 may be applied to other contents not described herein.

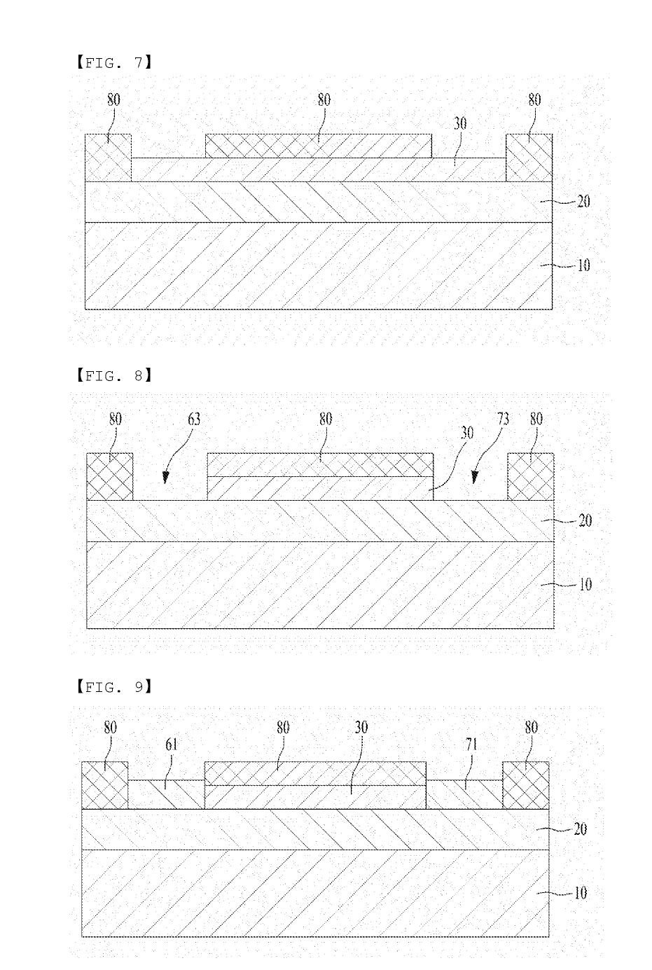

FIGS. 3 to 5 are sectional views illustrating a process of manufacturing a metal chalcogenide device according to an embodiment of the present invention. Hereinafter, a method of manufacturing a top-surface contact type metal chalcogenide device shown in FIG. 1 will be described with reference to FIGS. 3 to 5.

First, as shown in FIG. 3, a MoS₂ layer 30 is formed on a substrate 10. In this case, a silicon oxide (SiO₂) layer 20 may be disposed between the substrate 10 and the MoS₂ layer 30.

Next, as shown in FIG. 4, a mask pattern having an electrode shape is formed on the MoS₂ layer 30 using electron beam lithography or photolithography and Nb metal patterns 41 and 51 are then deposited thereon.

Next, as shown in FIG. 5, a chalcogen-containing gas, for example, H₂S gas, is injected at high temperature using a low-pressure chemical vapor deposition system to synthesize NbS₂ layers 42 and 52 from the Nb metal patterns 41 and 51. In this case, the synthesis process may be carried at a temperature ranging from 600° C. to 1000° C.

During the synthesis process shown in FIG. 5, some of the Nb atoms diffuse into MoS₂ to produce a p-type MoS₂ device shown in FIG. 1. In this case, the NbS₂ layers 42 and 52 are formed as a first electrode 40 and a second electrode 50.

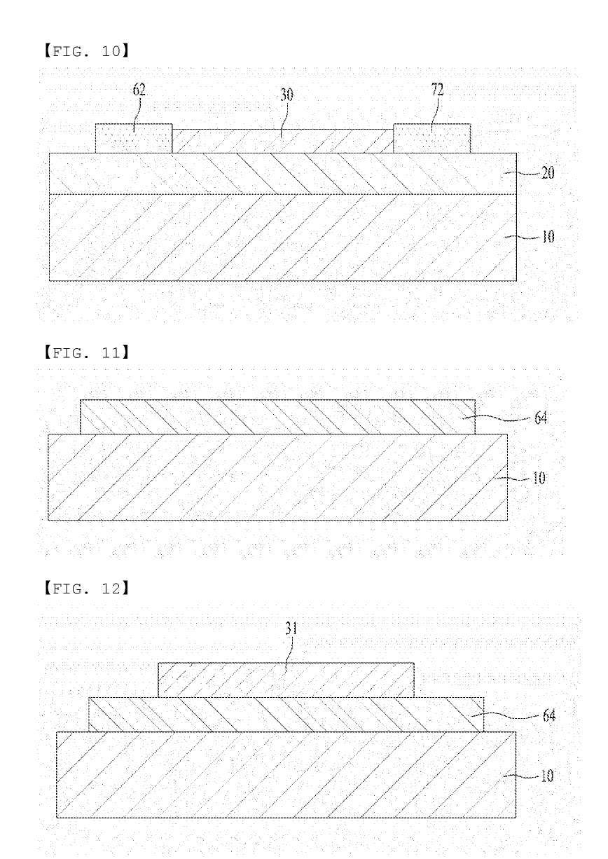

FIGS. 6 to 10 are sectional views illustrating a process of manufacturing a metal chalcogenide device according to another embodiment of the present invention. Hereinafter, a method of manufacturing a side-surface contact type metal chalcogenide device shown in FIG. 2 will be described with reference to FIGS. 6 to 10.

First, as shown in FIG. 6, a MoS₂ layer 30 is formed on a substrate 10. In this case, as mentioned above, the substrate 10 may be a silicon (Si) substrate. In this case, a silicon oxide (SiO₂) layer 20 may be disposed between the substrate 10 and the MoS₂ layer 30.

Next, as shown in FIG. 7, a mask pattern 80 having an electrode shape is formed on the MoS₂ layer 30 using electron beam lithography or photolithography. That is, a mask pattern 80 having an open part where the electrode is to be formed is obtained.

Next, as shown in FIG. 8, the MoS₂ layer 30 disposed in the part where the electrode is to be formed is removed. Removal of the MoS₂ layer 30 may be carried out by plasma etching. Through this process, electrode formation positions 63 and 73 where the electrodes contact the MoS₂ layer 30 in a side surface direction can be acquired.

Next, as shown in FIG. 9, Nb metal patterns 61 and 71 are deposited at the electrode formation positions 63 and 73 from which the MoS₂ layer 30 is removed. Next, the mask pattern 80 is removed.

Next, as shown in FIG. 10, a chalcogen-containing gas, for example, H₂S gas, is injected at high temperature using a low-pressure chemical vapor deposition system to synthesize NbS₂ layers 62 and 72 from the Nb metal patterns 61 and 61. In this case, the synthesis process may be carried at a temperature ranging from 600° C. to 1000° C.

During the synthesis process shown in FIG. 10, some of the Nb atoms diffuse into MoS₂ to produce a p-type MoS₂ device shown in FIG. 2. In this case, the NbS₂ layers 62 and 72 are formed as a first electrode 60 and a second electrode 70.

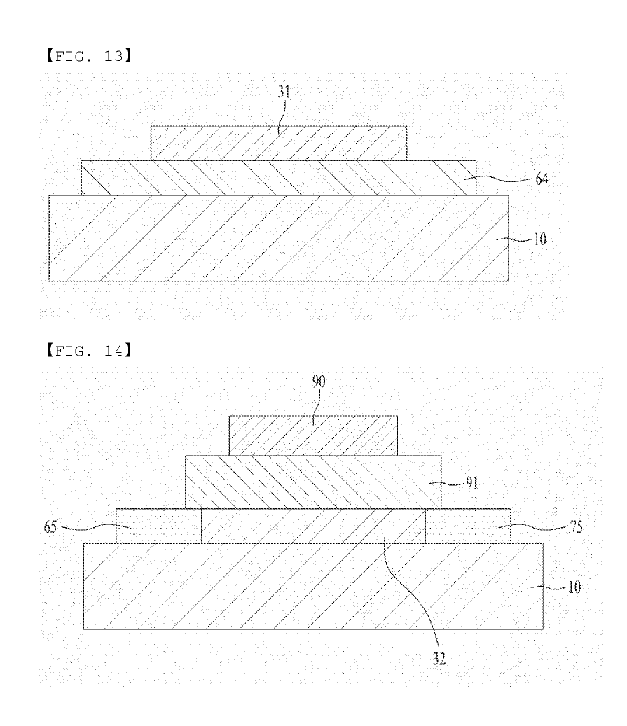

FIGS. 11 to 14 are sectional views illustrating a process of manufacturing a metal chalcogenide device according to another embodiment of the present invention. Hereinafter, a method of manufacturing a side-surface contact type metal chalcogenide device will be described with reference to FIGS. 11 to 14.

First, as shown in FIG. 11, a Nb thin film 64 is deposited by electron beam (e-beam) deposition or sputtering on the substrate 10 and is then patterned such that the Nb thin film 64 includes a channel and an electrode.

Next, as shown in FIG. 12, a Mo thin film 31 is deposited by electron beam deposition or sputtering on the Nb thin film 64 and then patterned in the form of a channel.

Next, as shown in FIG. 13, a H₂S gas is injected at high temperature using a low-pressure chemical vapor deposition system. In this process, the Nb thin film 64 is synthesized into NbS₂ which forms electrodes 65 and 75, and the Mo thin film 31 disposed in the channel part is replaced and doped with Nb, and is synthesized into a p-type MoS₂ thin film 32. In this case, the synthesis process may be carried at a temperature ranging from 600° C. to 1000° C.

Through this process, a side-surface contact type back-gate type device can be formed, as shown in FIG. 2. For this purpose, as mentioned above, a separate gate electrode may be provided under the substrate shown in FIG. 2.

Meanwhile, as shown in FIG. 14, a gate insulator 91 and a gate electrode 90 may also be formed on the p-type MoS₂ thin film 32 to manufacture a top-gate type device. The gate electrode 90 may be formed using gold (Au).

As mentioned above, a separate metal electrode may be formed on the NbS₂ electrodes 65 and 75. At this time, the metal electrodes may be connected through a via hole.

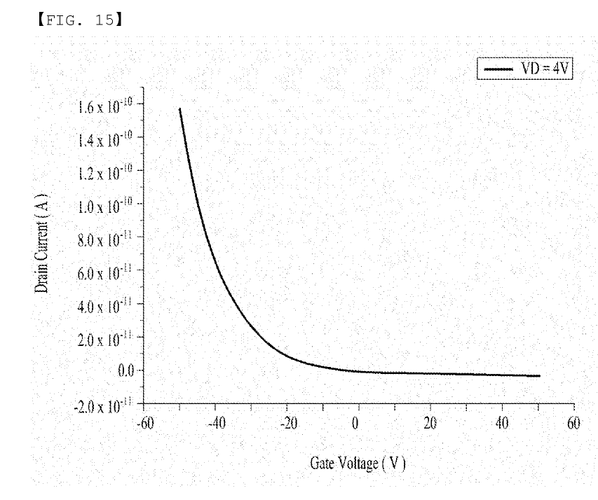

FIG. 15 is a graph showing a transfer curve of a metal chalcogenide device.

FIG. 15 shows a transfer curve of a metal chalcogenide device exhibiting properties of a p-type semiconductor.

Meanwhile, although embodiments according to the present invention disclosed in the specification and the drawings have been provided as specific examples for illustrative purposes, they should not be construed as limiting the scope of the present invention. It will be apparent to those skilled in the art that various modifications and variations can be made in the present invention without departing from the spirit or scope of the invention.

### INDUSTRIAL APPLICABILITY

According to the present invention, a metal chalcogenide layer having p-type conductivity can be provided and contact resistance of the electrode of the metal chalcogenide device can be greatly reduced.

1. A metal chalcogenide device comprising:
a substrate;
a metal chalcogenide layer with a first conductivity disposed on the substrate; and
a first electrode and a second electrode spaced from each other on an upper surface or a side surface of the metal chalcogenide layer, the first electrode and the second electrode comprising metal chalcogenide.

2. The metal chalcogenide device according to claim 1, wherein the first conductivity is p-type.

3. The metal chalcogenide device according to claim 1, wherein at least one of the first electrode and the second electrode comprises Nb.

4. The metal chalcogenide device according to claim 1, wherein the metal chalcogenide layer comprises MoS₂.

5. The metal chalcogenide device according to claim 1, wherein at least one of the first electrode and the second electrode comprises NbS₂.

6. The metal chalcogenide device according to claim 1, wherein the metal chalcogenide layer contacts at least one of the first electrode and the second electrode in a side surface direction.

7. The metal chalcogenide device according to claim 1, wherein a diffusion area having a relatively high first conductivity is disposed between the metal chalcogenide layer and at least one of the first electrode and the second electrode.

8. The metal chalcogenide device according to claim 1, further comprising:
a gate insulator disposed on the metal chalcogenide layer; and
a gate electrode disposed on the gate insulator.

9. A metal chalcogenide device comprising:
a substrate;
a channel layer comprising a p-type MoS₂ thin film disposed on the substrate;
a first electrode connected to the channel layer at a first position in a side surface direction, the first electrode comprising Nb;
a second electrode connected to the channel layer in a side surface direction at a second position spaced from the first position, the second electrode comprising Nb; and
a diffusion area disposed at at least one position of between the first electrode and the channel layer, and between the second electrode and the channel layer, the diffusion area being a region where a Nb atom diffuses into the channel layer.

10. The metal chalcogenide device according to claim 9, wherein the diffusion area has a higher conductivity than that of the channel layer.

11. The metal chalcogenide device according to claim 9, wherein the Nb atom is used as a dopant in the channel layer.

12. The metal chalcogenide device according to claim 9, further comprising:
a gate insulator disposed on the channel layer; and
a gate electrode disposed on the gate insulator.

13. A method of manufacturing a metal chalcogenide device comprising:
forming a first metal chalcogenide layer on a semiconductor substrate with a first conductivity where an oxide layer is disposed;
forming metal patterns spaced from each other at a position where the metal patterns contact the first metal chalcogenide layer; and
supplying a chalcogen-containing gas to the metal pattern to form the metal pattern into an electrode comprising a second metal chalcogenide.

14. The method according to claim 13, wherein the first metal chalcogenide layer comprises MoS₂.

15. The method according to claim 13, wherein the metal pattern comprises Nb.

16. The method according to claim 13, wherein the forming the metal pattern into the electrode comprises allowing the first metal chalcogenide layer to have the first conductivity by an atom contained in the metal pattern.

17. The method according to claim 13, wherein the first metal chalcogenide layer contacts the metal pattern in a side surface direction.

18. The method according to claim 13, wherein the forming the metal pattern comprises:
forming a mask pattern having an open part where the metal pattern is to be formed, on the first metal chalcogenide layer;
removing the opened first metal chalcogenide layer using the mask pattern;
forming the metal pattern in the area from which the first metal chalcogenide layer is removed; and
removing the mask pattern.

19. The method according to claim 18, wherein the first conductivity is p-type.

20. The method according to claim 13, further comprising:
forming a gate insulator between the metal patterns; and
forming a gate electrode on the gate insulator.
